(19) United States
(12) Patent Application Publication
(10) Pub. No.: US 2012/0037815 A1
(43) Pub. Date: Feb. 16, 2012

(54) TEM PHASE PLATE LOADING SYSTEM

(76) Inventors: Yunn-Shin Shiue, Taipei (TW); Shao-Kang Hung, Hsinchu (TW); I-Hui Chen, Taipei (TW); Chia-Seng Chang, Taipei (TW)

(21) Appl. No.: 13/193,951

(22) Filed: Jul. 29, 2011

Related U.S. Application Data
(60) Provisional application No. 61/374,077, filed on Aug. 16, 2010.

(51) Int. Cl. H01J 37/20; H01J 37/18

(52) U.S. Cl. 250/441.11

(57) ABSTRACT

A phase plate loading system, which can be installed on any commercial TEM (transmission electron microscope) without modifying its optical or lens design, includes an airlock chamber and a transport unit. The airlock chamber is disposed adjacent to the specimen section of the TEM. The transport unit transfers a phase plate into the TEM through the airlock chamber.

### CROSS REFERENCE TO RELATED APPLICATIONS

This Non-provisional application claims the benefit of the filing date of provisional application No. 61/374,077 filed Aug. 16, 2010, under 35 USC & 119 (e) (1).

### BACKGROUND OF THE INVENTION

1. Field of Invention

The present invention relates to a phase plate loading system of a transmission electron microscope (TEM).

2. Related Art

The success of a phase TEM adopting a phase plate device is considered to have a high potential to make some impact in various fields, including biology and materials sciences. With a proper phase TEM and the appropriate wave reconstruction method, it is possible to reveal bio-structure information, which can never be obtained by the conventional TEM. In order to develop a phase TEM that is applicable for imaging, tremendous technical difficulties have to be overcome: (1) loading the phase plate into a TEM must not degrade the functions of the TEM; (2) the phase plate needs to be positioned at the back focal plane with a high scale of precision; (3) fabrication of a reliable phase plate is technically challenging; (4) low dose imaging is needed while taking images of vulnerable specimens.

Various phase plate designs have been proposed, including Zernike-type and Hilbert-type phase plates. The Zernike-type phase plate is suitable for thin-film type, electrostatic type and magnetic (vector potential) type phase plates. The Hilbert-type phase plate is suitable for thin-film style and magnetic style phase plates. In any case, it is essential to load a phase plate in any form into the limited space within the TEM chamber for increasing the phase contrast, without affecting the normal operation of the TEM.

In the conventional art, the optical design of the TEM must be modified in order to load the phase plate into the TEM. For example, the optical design may be modified by adding a transfer lens doublet in the TEM. The modification of the TEM optical design is complicated and expensive, thus is not preferred by TEM users. The users may choose another method to place the phase plate into the TEM, which includes the following steps: shutting down the TEM, opening the TEM chamber, placing the phase plate into the TEM chamber, sealing the chamber, vacuuming the TEM, and finally restarting the TEM. However, this method is very inconvenient and risky, because of the time consuming for changing the phase plate (usually several days) and the possibility of damaging expensive internal components while opening the TEM chamber.

Therefore, it is an important subject of the present invention to provide a phase plate loading system, which can load the phase plate into the TEM without modifying its optical design, and perform the phase plate loading procedure safely without shutting down the TEM, thereby decreasing the time consumption for the phase plate loading procedure, and avoiding damaging internal components of the TEM.

### SUMMARY OF THE INVENTION

In view of the foregoing, an object of the present invention is to provide a phase plate loading system, which can load the phase plate into the TEM without modifying its optical design, and perform the phase plate loading procedure without shutting down the TEM, thereby decreasing the time consumption for the phase plate loading procedure and avoiding damaging internal components of the TEM.

To achieve the above object, the present invention discloses a phase plate loading system applied to a TEM. The phase plate loading system includes an airlock chamber and a transport unit. The airlock chamber is disposed adjacent to a specimen section of the TEM. The transport unit transfers a phase plate into the TEM through the airlock chamber and an opening port of the specimen section.

In one embodiment of the invention, the airlock chamber is connected with a pump unit. Herein, the pump unit can be an independent pump unit or a pumping unit of the TEM.

In one embodiment of the invention, the opening port of the specimen section includes an EDS (energy dispersive x-ray spectroscope) port or an objective aperture port.

In one embodiment of the invention, the specimen section includes a specimen chamber; and the airlock chamber and the specimen chamber are linked to each other and separated by a gate valve.

In one embodiment of the invention, the transport unit further includes a guiding rail disposed on the airlock chamber.

In one embodiment of the invention, the phase plate is an electrostatic type phase plate, or a magnetic type phase plate, or a thin-film type phase plate.

In one embodiment of the invention, the transport unit includes a motor for transferring the phase plate. Preferably, the transport unit further includes a loading rod connected with the motor. Preferably, the transport unit further includes a phase plate holder connected with the motor. Herein, the phase plate holder carries the phase plate.

In one embodiment of the invention, the system further includes a loading monitor unit for monitoring the specimen section, more particularly, a position of the phase plate in the specimen section. Preferably, the loading monitor unit includes a camera or a sensor.

In one embodiment of the invention, the specimen section includes an ACD fin (anti-contamination device fin), and the phase plate is installed inside the ACD fin. Preferably, the specimen section includes a specimen holder, and the phase plate is installed between the specimen holder and the ACD fin.

As mentioned above, the TEM phase plate loading system of the invention can transfer the phase plate into the TEM through the airlock chamber, which is disposed adjacent to the specimen section of the TEM, so that modifying the optical design of the TEM is not necessary. In other words, the phase plate loading system of the invention can be installed on any commercial TEM. Compared with the prior art, the present invention discloses an airlock chamber for pre-vacuuming the phase plate before transferring it into the TEM. Thus, the conventional procedure for loading the phase plate including the steps of shutting down the TEM, opening the TEM chamber, sealing the chamber, and vacuuming the TEM is unnecessary, thereby reducing the time consuming for the loading procedure. For instance, the loading time may be reduced from several days to less than one hour. Moreover, the phase plate can be loaded without opening the chamber of the TEM. The present invention allows user to rapidly operate the phase TEM without damaging the internal components of the TEM.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing a TEM equipped with a phase plate loading system of the present invention;

FIG. 2 is a schematic diagram showing the airlock chamber and the transport unit of the phase plate loading system of FIG. 1;

FIG. 3 is a schematic diagram showing the detailed structure of the transport unit of the invention;

FIG. 4A is a side view of the transport unit equipped in the TEM of the invention;

FIG. 4B is a top view of the transport unit equipped in the TEM of the invention; and

FIG. 4C and FIG. 4D are schematic diagrams showing the phase plate, which is positioned and aligned.

### DETAILED DESCRIPTION OF THE INVENTION

The present invention will be apparent from the following detailed description, which proceeds with reference to the accompanying drawings, wherein the same references relate to the same elements.

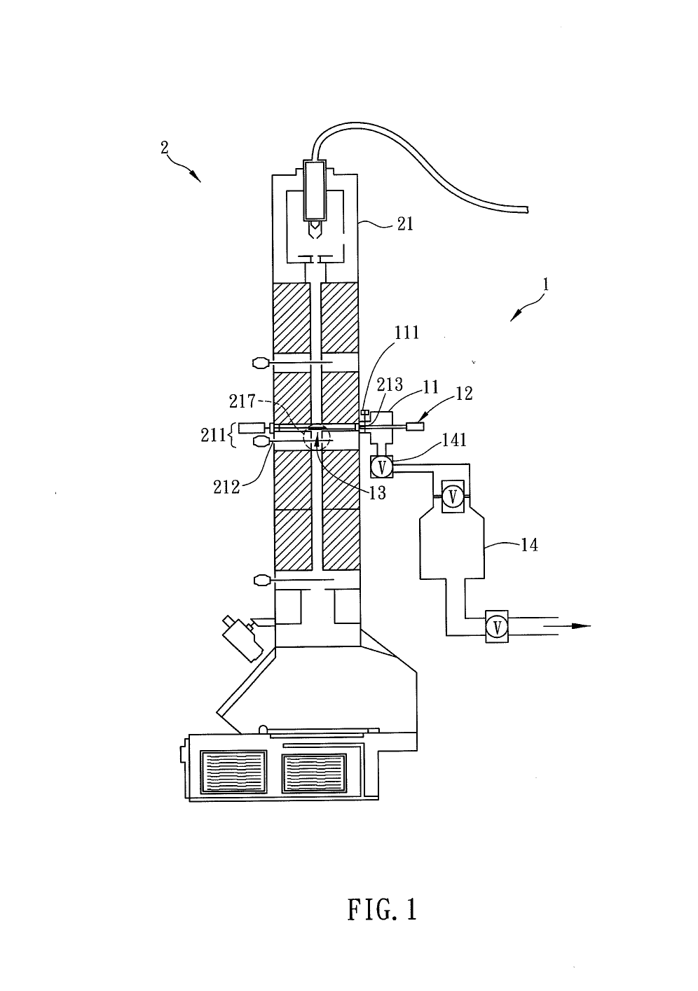

FIG. 1 is a schematic diagram showing a TEM equipped with a phase plate loading system 1 of the present invention. With reference to FIG. 1, the phase plate loading system 1 applied to a TEM 2 includes an airlock chamber 11 and a transport unit 12.

As shown in FIG. 1, the TEM 2 is a transmission electron microscope, which is composed of a column portion 21, a vacuum system (not shown) and a control system (not shown). The column portion 21 includes an electron gun section, several lenses sections, a specimen loading section, a fluorescent screen section, a camera, etc. These components are usually installed from top to bottom so as to form a cylindrical configuration. The vacuum system is composed of various pumps and several vacuum gate valves, and is connected to the column portion 21.

In the present invention, an airlock chamber 11 is additionally configured outside the TEM 2. The airlock chamber 11 is installed adjacent to the specimen section 211 of the TEM 2. The specimen section 211 is the section where the specimen loading port is configured, and it includes a specimen chamber 217. The opening ports of the specimen section 211 may include an objective aperture port 212 and an EDS (energy dispersive x-ray spectroscope) port 213. The airlock chamber 11 can be positioned in any idle opening port of the specimen section 211 and linked with the specimen chamber 217 inside the TEM 2 through a gate valve 111. The material analysis function of EDS is usually not needed in the TEM 2 cooperated with the phase plate 13 when the TEM 2 is dedicated for bio-imaging, thus the EDS port 213 is an open port. Therefore, the EDS port 213 can be used to install the phase plate loading system 1 of the invention.

The airlock chamber 11 has to be small enough to fit into the limited space around the opening ports of the specimen section 211 without blocking other components.

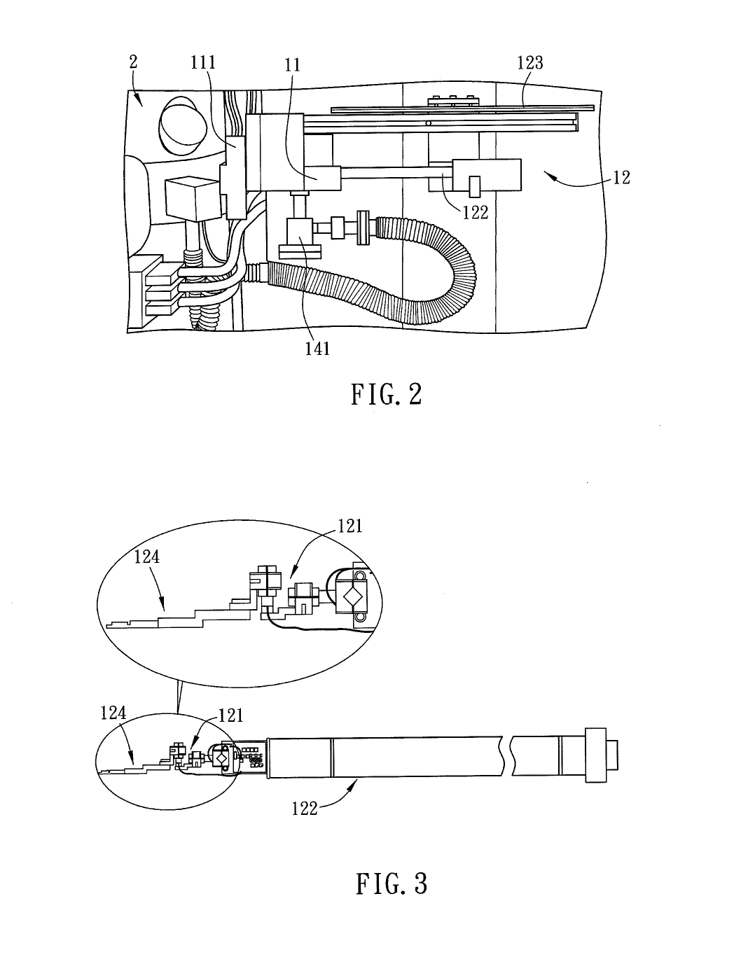

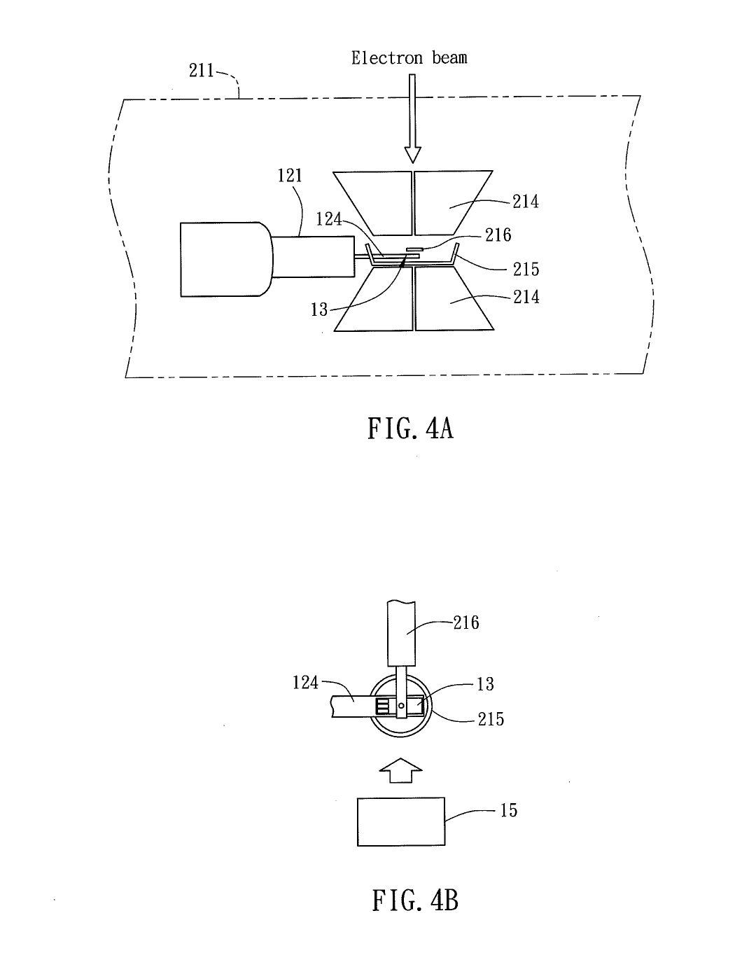

FIG. 2 is a schematic diagram showing the airlock chamber 11 and the transport unit 12 of the phase plate loading system 1, and FIG. 3 is a schematic diagram showing the detailed structure of the transport unit 12 of the invention. Referring to FIG. 2 and FIG. 3, the airlock chamber 11 is connected with a pump unit 14. In this embodiment, the pump unit 14 is a pump independent from the vacuum system of the TEM 2. In practice, the pump unit 14 may be a pumping unit of the TEM 2 depending on the needs of the users. Moreover, the pumping unit may be integrated in the vacuum system.

The transport unit 12 transfers a phase plate 13 into the TEM 2. In this embodiment, the transport unit 12 includes a motor 121 for driving to transfer the phase plate 13. Any driving mechanism other than a motor driving can also be adopted on the transport unit 12. The detailed structure of the transport unit 12 will be described hereinafter.

After loading the phase plate 13, one end of the transport unit 12 enters the airlock chamber 11. Then, the phase plate pre-pumping valve 141 is opened, so that the pump unit 14 can pump out the air inside the airlock chamber 11. After the airlock chamber 11 reaches the desired vacuum state, the gate valve 111 between the airlock chamber 11 and the column is opened, and then the phase plate 13 is transferred into the column inside the TEM 2. In this embodiment, the complex procedure of the prior art, which includes the following steps of shutting down the TEM 2, opening the specimen chamber, placing the phase plate 13 into the specimen chamber, sealing the chamber, vacuuming the TEM 2, and finally restarting the TEM 2, is not needed. The phase plate loading system 1 of the invention does not need the exhaust time for vacuum after loading the phase plate 13. Moreover, the present invention does not need to open the TEM 2 so as to prevent it from being damaged. For example, if the phase plate loading system 1 of the invention is installed on a commercial TEM equipped with a turbo molecular pumping system, the time needed for replacing a phase plate 13 and reloading it into the airlock chamber 11 and for the system to reach the vacuum condition for operating can be accomplished within 30 minutes. This is quite efficient and useful for practical applications, considering the phase plates 13 often need to be replaced and reloaded. It should be noted that pumping times for the TEM 2 vary with the equipped pumping systems.

Referring to FIG. 2 and FIG. 3, the transport unit 12 further includes a loading rod 122, a guiding rail 123, and a phase plate holder 124. The loading rod 122 and the phase plate holder 124 are connected to two ends of the motor 121, respectively. The guiding rail 123 can be attached on the top of the airlock chamber 11 to guide the loading rod 122 into the column of the TEM 2. This is a safety design so that the risk of damaging the phase plate holder 124 during loading and unloading is greatly reduced. In addition, the phase plate holder 124 is used to carry the phase plate 13.

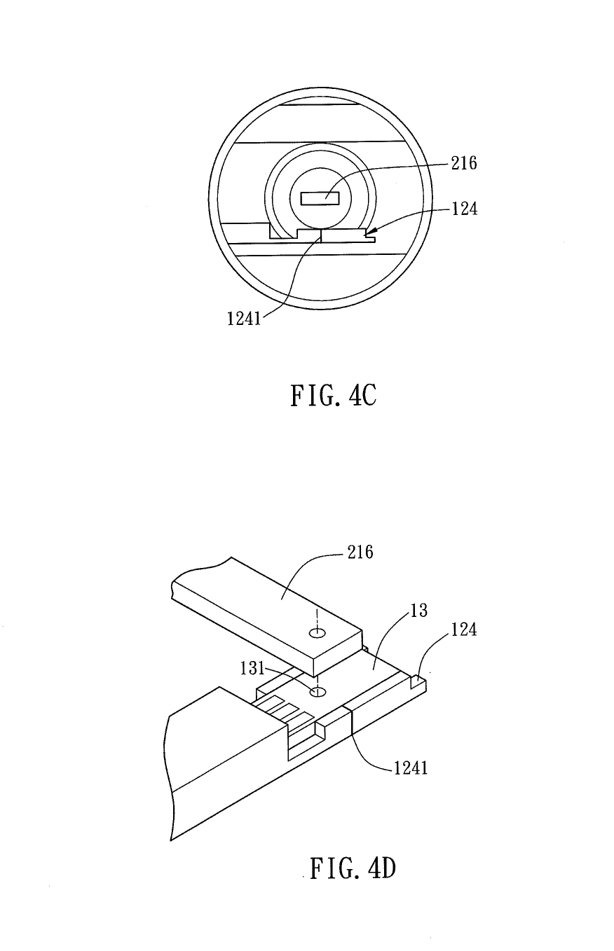

FIG. 4A is a side view of the transport unit 12, and FIG. 4B is a top view of the transport unit 12 when the phase plate 13 is placed inside the TEM 2 of the invention. The phase plate holder 124 is used to carry the phase plate 13, such as an electrostatic type phase plate, a magnetic type phase plate, or a thin-film type phase plate. In addition, the specimen section 211 may further include an ACD (anti-contamination device) fin 215 and a specimen holder 216, which are disposed between two pole pieces 214 of the TEM 2. The phase plate 13 is carried by the phase plate holder 124, which is connected to the motor 121, and is transferred into the specimen chamber. More particularly, the phase plate 13 is transferred to the location between the specimen holder 216 and the ACD fin 215. In this embodiment, the ACD fin 215 near the EDS port 213 is slightly trimmed to clear out a path for loading the phase plate 13, and kept in place to serve its function.

With reference to FIG. 4B, a phase plate loading system 1 of the invention further includes a loading monitor unit 15 for monitoring the phase plate 13 transferred from the airlock chamber 11 to the column 21. More particularly, the loading monitor unit 15 can monitor whether the phase plate 13 reaches a specific position. In this embodiment, the loading monitor unit 15 includes a camera or a sensor for monitor the position of the phase plate 13 inside the specimen section 211. The loading monitor unit 15 can be disposed outside the specimen section 211.

FIG. 4C and FIG. 4D are schematic diagrams showing the phase plate 13, which is positioned and aligned by utilizing the loading monitor unit 15. Practically, the loading monitor unit 15 allows users to observe the movement of the phase plate holder 124 carrying the phase plate 13 on a computer screen, and thus greatly decreases the chances of breaking the vulnerable phase plate 13 and the phase plate holder 124, and also significantly speeds up the positioning of the phase plate 131. For example, as shown in FIG. 4D, the phase plate 13 can be positioned and aligned with the electron beam passing through the specimen holder 216. As shown in FIGS. 4C and 4D, a line 1241 can be marked on the side surface of the phase plate holder 124 in advance with respect to different phase plates 13, thereby identifying the exact position of the phase plate 131. When the phase plate holder 124 is inserted to a position under the specimen holder 216, the user can observe the phase plate holder 124 from one side so as to position the phase plate 13 by aligning the line 1241 to the center of the specimen holder 216, thereby positioning the phase plate 131 on the beam path of the electron beam. Besides, when different phase plates 13 are used, the line 1241 can be easily erased and re-marked for positioning different phase plates 13. The phase plate 13 can be aligned by manual control or by automatic control. In either control method, the time consumption for loading the phase plate 13 can be sufficiently reduced.

As mentioned above, the TEM phase plate loading system of the invention can transfer the phase plate into the TEM through the airlock chamber, which is disposed adjacent to the specimen section of the TEM, so that it is unnecessary to either modify the optical design of the TEM or shut down and re-start the TEM. In other words, the phase plate loading system of the invention can be installed on any commercial TEM. Compared with the prior art, the present invention discloses an airlock chamber for pre-vacuuming the phase plate before transferring it into the TEM. Thus, the conventional procedure for loading the phase plate including the steps of shutting down the TEM, opening the TEM, placing the phase plate into the TEM, and re-starting the TEM, is unnecessary, thereby reducing the time consuming for the TEM phase plate loading procedure. For instance, the loading time may be reduced from several days to less than one hour. Moreover, the phase plate can be loaded without opening the chamber of the TEM, so that TEM can be protected from being damaged. The present invention allows the user to rapidly operate the TEM equipped with TEM phase plates.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A phase plate loading system applied to a TEM (transmission electron microscope), comprising:
an airlock chamber disposed adjacent to a specimen section of the TEM; and
a transport unit transferring a phase plate into the TEM through the airlock chamber.

2. The system according to claim 1, wherein the airlock chamber is connected with a pump unit.

3. The system according to claim 2, wherein the pump unit is an independent pump unit or a pumping unit of the TEM.

4. The system according to claim 1, wherein the specimen section comprises an EDS (energy dispersive x-ray spectroscope) port or an objective aperture port or any open port.

5. The system according to claim 1, wherein the specimen section comprises a specimen chamber, and the airlock chamber and the specimen chamber are linked to each other and separated by a gate valve.

6. The system according to claim 1, wherein the transport unit further comprises a guiding rail disposed on the airlock chamber.

7. The system according to claim 1, wherein the phase plate is an electrostatic type phase plate, or a thin-film type phase plate, or a magnetic type phase plate.

8. The system according to claim 1, wherein the transport unit comprises a motor for transferring the phase plate.

9. The system according to claim 8, wherein the transport unit further comprises a loading rod connected with the motor.

10. The system according to claim 8, wherein the transport unit further comprises a phase plate holder connected with the motor.

11. The system according to claim 10, wherein the phase plate holder carries the phase plate.

12. The system according to claim 1, further comprising:
a loading monitor unit for monitoring a position of the phase plate in the specimen section.

13. The system according to claim 12, wherein the loading monitor unit comprises a camera or a sensor.
